(19) United States
(12) Patent Application Publication
(10) Pub. No.: US 2002/0034311 A1
(43) Pub. Date: Mar. 21, 2002

(54) Modular multiple channel audio signal conditioning interface

(76) Inventors: Joseph D. Kotyuk, West Springfield, PA (US); Eric J. Erickson, Waterford, PA (US)

Correspondence Address: WAYNE L. LOVERCHECK, LOVERCHECK & LOVERCHECK PC, 931 STATE ST., ERIE, PA, 16501-1451, US

(21) Appl. No.: 09/935,898

(22) Filed: Aug. 23, 2001

Related U.S. Application Data
(60) Provisional application No. 60/233,773, filed on Sep. 19, 2000.
(60) Provisional application No. 60/298,754, filed on Jun. 18, 2001.

(51) Int. Cl. H03G 5/00; H03G 3/00; H04R 5/02

(52) U.S. Cl. 381/104; 381/307; 381/98

(57) ABSTRACT

A modular multiple channel audio signal interface for use with discrete component audio entertainment systems such as home and car stereo systems. The interface contains, within a single housing, signal conditioning means for compensating for signal level imbalances which occur when components having incompatible audio signal voltage levels are connected within the same entertainment system. Manual adjustment means allow for selecting the correction or compensation most appropriate given the incompatibility of the components of the system. The interface is designed for use in component or modular systems having a head unit such as a preamplifier. The head unit receiving inputs from a variety of devices such as CDs, cassettes, DVDs, stereo cable boxes, tuners, etc. The output from the head unit is connected to the interface, which conditions the signal before outputting it to an amplifier.

### CROSS REFERENCE TO RELATED APPLICATIONS

This application claims the benefit of U.S. Provisional Application Serial No. 60/233,773 filed Sep. 19, 2000, and U.S. Provisional Application Serial No. 60/298,754, filed Jun. 18, 2001.

### STATEMENT REGARDING FEDERALLY SPONSORED RESEARCH OR DEVELOPMENT

Not Applicable

### BACKGROUND OF THE INVENTION

The present invention relates generally to audio signal distortion correction circuits. More particularly, it relates to a modular audio signal distortion correcting and conditioning interface, which may be used to enhance compatibility between component audio subsystems.

Audio component entertainment systems are now available in many different configurations from a variety of manufacturers. These entertainment systems are used in a wide variety of applications ranging from automobile sound systems to “surround sound” home entertainment systems. Some of these systems are “modular” in that they are comprised of a series audio signal generating and processing subsystems which are separately housed. A typical modular system may include a “head” unit such as a receiver or pre-amplifier. The head unit typically accepts audio signal inputs from a media device such as a compact disk player, cassette deck, etc., and includes controls accessible to the user for adjusting the volume, bass, treble, and balance, and for selecting the audio signal source. The head unit outputs a signal, which is then amplified by a power amplifier, which is also separately housed. When the various subsystems or modules are from a single manufacturer they may be “matched” so that distortion produced by incompatible inter-module signal levels is virtually non-existent. However, it is often desirable to connect subsystems from various manufacturers in order to take advantage of features and capabilities, which may not be available from a single manufacturer. In the automotive environment in particular, due to the relatively recent emergence of high quality, multiple module, entertainment systems, some of which are factory pre-installed and designed specifically for integration with factory components, audio signal “mismatches” can cause noticeable distortion in the audible output of the system which cannot be corrected by pre-amplifier controls. The distortion may be produced by under drive, over drive, level imbalance, or other factors as is well known in the art. Because of the relatively constricted environment provided by an automobile, any additional modules must be relatively compact, and have controls, which are easily accessible and capable of manipulation both before and after installation.

U.S. Pat. No. 4,429,181 issued to Freadman discloses a three way audio system, which outputs a separate audio signal to each of three speakers in three frequency ranges. A separate power amplifier is provided for each speaker. Connected between a common pre-amp and each of the power amplifiers is an electronic resonance control correction circuit. The pre-amp, power amplifier, and correction circuits are all mounted in a single housing.

U.S. Pat. No. 4,438,414 issued to Blachot discloses a multi-channel tone control circuit, which can be fabricated on a single integrated chip.

None of the above inventions and patents, taken either singly or in combination, is seen to describe the instant invention as claimed.

### BRIEF SUMMARY OF THE INVENTION

The present invention overcomes the disadvantages of the prior art by providing a modular multiple channel audio signal interface for use with discrete component audio entertainment systems such as home and car stereo systems. The interface contains, within a single housing, signal conditioning means for compensating for signal level imbalances, which occur when components having incompatible audio signal voltage levels are connected within the same entertainment system. Manual adjustment means allow for selecting the correction or compensation most appropriate given the incompatibility of the components of the system. The interface is designed for use in component or modular systems having a head unit such as a preamplifier, the head unit receiving inputs from a variety of devices such as CDs, cassettes, DVDs, stereo cable boxes, tuners, etc. The output from the head unit is connected to the interface, which conditions the signal before outputting it to an amplifier.

It is an object of the present invention to provide an interface between an audio entertainment head unit and a power amplifier.

It is another object of the present invention to provide an interface between an audio entertainment head unit and a power amplifier, which is housed in a single module.

It is another object of the present invention to provide an interface between an audio entertainment head unit and a power amplifier, which can compensate for signal level imbalances.

It is another object of the present invention to provide an interface between an audio entertainment head unit and a power amplifier, which can correct low frequency error.

It is another object of the present invention to provide an interface between an audio entertainment head unit and a power amplifier, which allows for manual or automatic adjustment of channel imbalance.

It is another object of the present invention to provide an interface between an audio entertainment head unit and a power amplifier, which allows for manual adjustment of the compression or expansion of the dynamic range of the audio signal. It is another object of the present invention to provide an interface between an audio entertainment head unit and a power amplifier, which can reduce noise in the audio signal.

It is another object of the present invention to provide an interface between an audio entertainment head unit and a power amplifier that is simple in construction, economical to manufacture and simple and efficient to use.

With the above and other objects in view, the present invention consists of the combination and arrangement of parts hereinafter more fully described, illustrated in the accompanying drawing and more particularly pointed out in the appended claims, it being understood that changes may be made in the form, size, proportions and minor details of construction without departing from the spirit or sacrificing any of the advantages of the invention.

### BRIEF DESCRIPTION OF THE SEVERAL VIEWS OF THE DRAWING(S)

FIG. 1 is a block diagram of the preferred embodiment of a multi-channel distortion correction interface illustrating a possible arrangement of the various modules connected to the interface.

FlG. 2 illustrates the effect the interface has on input audio signal waveforms.

FIG. 3 is a schematic diagram of the circuitry for each channel of the multi-channel distortion correction interface.

FIG. 4 is a block diagram of the circuitry for each channel of the multi-channel distortion correction interface illustrating the major components of the circuitry and the signal flow therethrough.

### DETAILED DESCRIPTION OF THE INVENTION

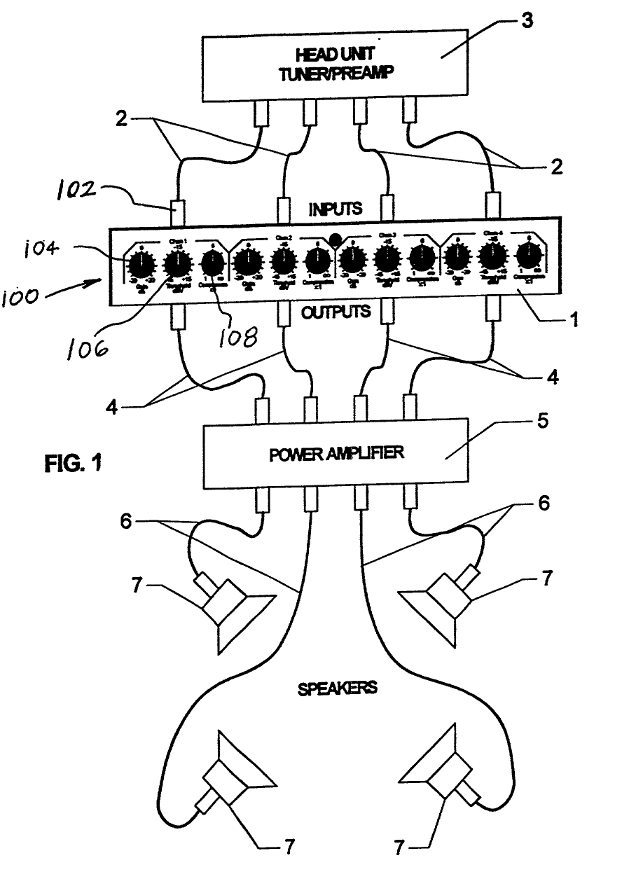

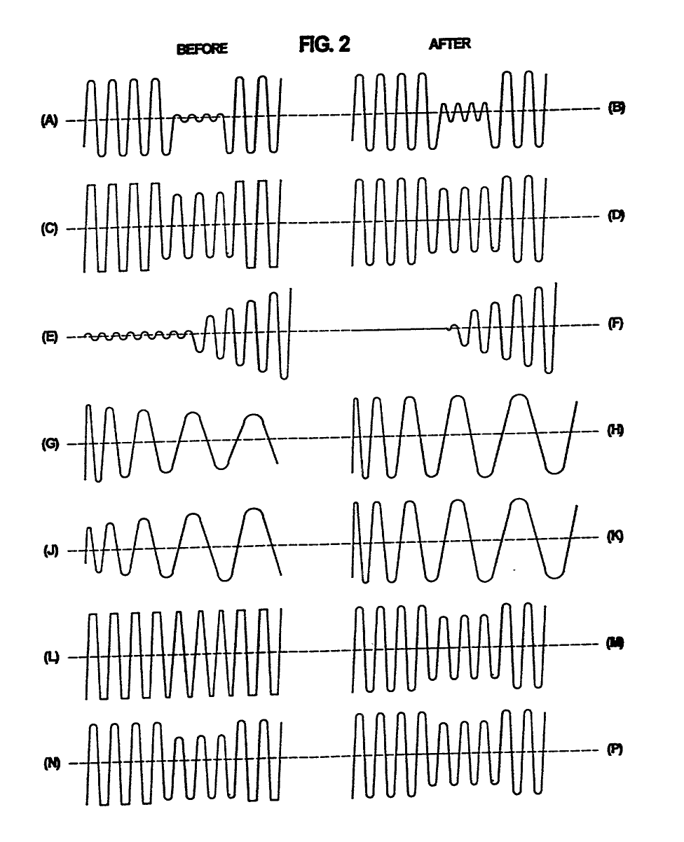

Referring now to FIGS. 1 through 4 of the present invention, shown is modular multiple channel audio signal interface 100. As can be seen in FIG. 1, interface 100 may be housed in box 1 and includes four input terminals 102 for accepting inputs through lines 2 from a head unit, such as preamplifier 3, a plurality of variable manual controls including, for each channel, gain control 104, threshold control 106, and compression control 108. A plurality of output terminals 110 are adapted for connection through lines 4 to an output device, such as power amplifier 5. Power amplifier 5 amplifies the signal from interface 100 and outputs the amplified signal through lines 6 to an output device, such as speakers 7. While in the example shown, interface 100 has four channels, fewer or more channels may be facilitated by interface 100.

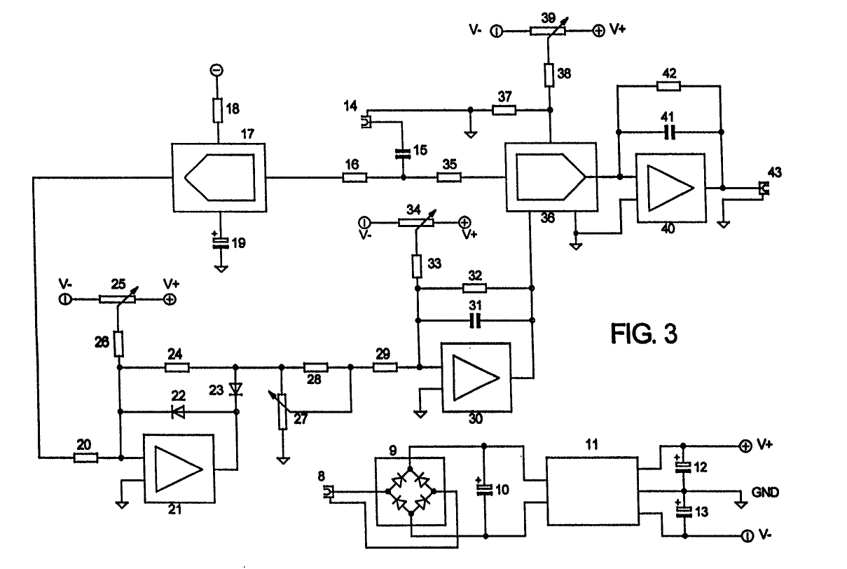

In FIG. 3, which shows the circuitry of one channel of the modular multiple channel audio signal conditioning interface 100 made in accordance with the preferred embodiment of the device, it can e seen that the audio signal from (head unit) preamplifier 3 is connected to input connector 14. This signal passes through DC isolation capacitor 15 where the remaining signal components are routed through input biasing resistor 16 to a true root mean square (RMS) AC to DC converter 17.

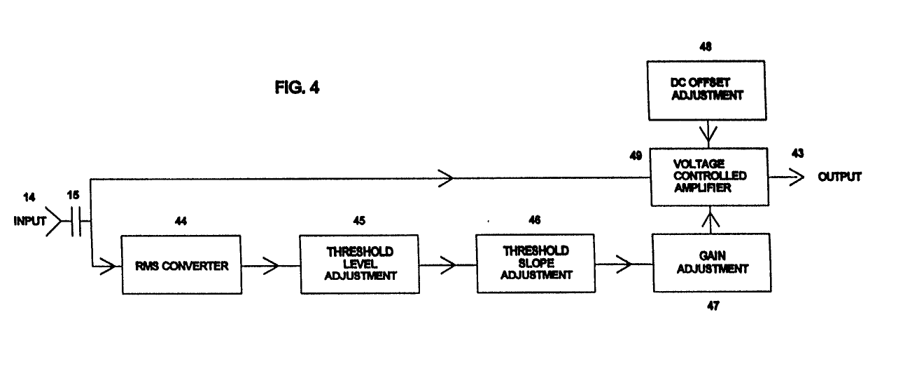

The RMS converter circuitry (block 44 of FIG. 4) includes bias resistor 18 connected at one side to the negative bias voltage and the other to RMS converter 17. Damping capacitor 19 is connected to RMS converter 17 to insure proper operation of RMS converter 17. RMS converter 17 output is routed through limiting resistor 20 to the inverting input of operation amplifier 21.

The threshold adjustment circuit (Block 45 of FIG. 4) allows for adjusting the amplitude of the input audio signal above a predetermined minimum amplitude. The threshold adjustment circuitry includes positive feedback diode 22, which is connected between operational amplifier 21 output and its inverting input. Negative feedback diode 23 connected in series with resistance 24 is also connected between operational amplifier 21 output and its inverting input. Variable resistor or potentiometer 25 is connected such that the negative bias is on one side and the positive bias is on the other, and the wiper of which is connect to current limiting resistance 26, which is in turn also connected to the inverting input of operational amplifier 21.

The output of the threshold circuit is routed from the junction of diode 23 and feedback resistance 24 to the threshold slope adjustment network (Block 46 in FIG. 4) at the junction of resistance 28 and variable resistance 27. The opposite end of variable resistance 27 is connected to ground and the wiper is connected to the opposite end of resistance 28.

The signal at the junction of variable resistance 27 and resistance 28 is connected to current limiting resistance 29 of the gain adjustment circuitry. The other end of resistance 29 is connected to the inverting input of operational amplifier 30. Feedback capacitance 31 and resistance 32 are connected between operational amplifier 30 output and its inverting input. Variable resistor or potentiometer 34 is connected such that the negative bias is on one side and the positive bias is on the other, and the wiper of which is connected to current limiting resistance 33, which is in turn also connected to the inverting input of operational amplifier 30.

Operational amplifier 30 output is routed directly to the control input of voltage-controlled amplifier 36. The input audio signal at input connector 14 is routed through DC isolation capacitance 15 and limiting resistance 35. Voltage-controlled amplifier 36 output signal is connected to the inverting input of operational amplifier 40. Feedback capacitance 41 and resistance 42 are connected between operational amplifier 40 output and its inverting input. This constitutes the voltage controlled amplifier circuit 49 of FIG. 4.

The DC offset adjustment circuitry 48 (Block 48 in FIG. 4) comprises a resistor or potentiometer 39 connected such that the negative bias is on one side and the positive bias is on the other, and the wiper of which is connected to resistance 38, which is in turn connected to one side of resistance 37, whose other side is connected to ground. The junction of resistors 37 and 38 is connected to the DC offset input of voltage-controlled amplifier 36.

The device bias circuitry includes power supply 11 and diode bridge 9. DC input power is supplied to connector 8, which is connected to the inputs of diode bridge 9. Diode bridge 9 routes positive and negative levels of the bulk input power to the appropriate terminals of isolated switch-mode type integrated bipolar power supply 11. Bulk filter capacitor 10 is connected between the positive and negative terminals of the bulk power into power supply 11. Filter capacitors 12 and 13 are connected between power supply 1 outputs and ground respectively.

Referring now to FIG. 2, representative input and output waveforms for interface 100 are shown. FIGS. 2A and 2C show input signals having an undesirable peak to peak amplitude, which may produce an undesirable output from amplifier 5. FIGS. 2B and 2D show the result of amplitude level shifting by interface 100. It can be seen that the signal shown in FIG. 2C is actually clipping before level shifting is performed and would have resulted in a highly distorted output from amplifier 5. Similarly, FIGS. 2E and 2F, 2G and 2H, 2J and 2K, 2L and 2M, 2N and 2P show for various input signals the result of amplitude level shifting by interface 100.

In operation, interface 100 is connected within the audio system as shown in FIG. 1. The user then adjusts gain control 104, threshold control 106, compression control 108, and potentiometer 39 until a desirable audible output is achieved.

With particular reference to FIG. 4, it can be seen that input signal connector 14 is split after DC voltages isolating capacitor 15. The audible signal is then passed directly to voltage controlled amplifier 49, where it is amplified in accordance with the user settings, and the result of comparisons and adjustments performed by the RMS converter, represented by Block 44, the threshold level adjustment, represented by block 45, the threshold slope adjustment, represented by block 46, and the gain adjustment, represented by block 47. The DC signal received by voltage-controlled amplifier 49 determines the actual amplification, and therefore the amplitude of final output signal 43.

From the foregoing description, one skilled in the art can easily ascertain the essential characteristics of this invention and, without departing from the spirit and scope thereof, can make various changes and modifications of the invention to adapt it to various usages and conditions. For instance, device 100 may be packaged along with, or preprogrammed with, data from a number of different manufacturers so that the user can set the desired signal level adjustments without undue trial and error. For example, for a head unit from manufacturer X, a CD player from manufacturer Y, and a power amp from Manufacturer Z, the settings might be 7, 15, and 2, respectively for gain, threshold, and compression. Alternatively, the information may be available over the Internet where it would be continuously updated.

The foregoing specification sets forth the invention in its preferred, practical forms but the structure shown is capable of modification within a range of equivalents without departing from the invention which is to be understood is broadly novel as is commensurate with the appended claims.

The embodiments of the invention in which an exclusive property or privilege is claimed are defined as follows:

1. A multiple channel audio signal conditioning modular interface comprising:
a plurality of inputs for receiving audio signals from a corresponding plurality of outputs from a primary audio signal module;
each of said inputs connected to a corresponding signal conditioning circuit;
each of said circuits having both manually adjustable and automatic signal conditioning means;
each of said signal conditioning means capable of adjusting amplitude levels of said audio signals;
a plurality of outputs for outputting a conditioned signal from each of said conditioning circuits wherein said inputs, said outputs, and said signal conditioning circuits are all contained within a single housing.

2. The interface recited in claim 1 wherein each of said signal conditioning circuits generates a control voltage proportional to amplitude levels of said audio signals and wherein each of said manually controllable signal conditioning means includes a threshold circuit;
said threshold circuit having a potentiometer operatively connected thereto for adjusting a threshold voltage to a user desired voltage level, wherein when said control voltage drops below said threshold voltage said threshold circuit outputs a predetermined control voltage, and when said control voltage is above said threshold voltage said threshold circuit amplifies and outputs said control voltage.

3. The interface recited in claim 2 wherein said predetermined control voltage or said amplified control voltage affect said conditioned signal at a predetermined rate, and wherein either of said outputs from each of said threshold circuits is applied to a corresponding threshold slope circuit;
said threshold slope circuits controlling the rate at which said predetermined control voltage or said amplified control voltage affect said conditioned signal.

4. The interface recited in claim 3 wherein said threshold slope circuits include manual adjustment means for adjusting the rate at which said predetermined control voltage or said amplified control voltage affect said conditioned signal.

5. The interface recited in claim 1 wherein gain of said audio signal is controlled by said signal conditioning circuits.

6. The interface recited in claim 5 wherein the signal conditioning circuits include means for manually adjusting the gain of said audio signal.

7. The interface recited in claim 1 wherein the signal conditioning circuits include means for filtering noise.
